(19) United States
(12) Patent Application Publication
(10) Pub. No.: US 2010/0123162 A1
(43) Pub. Date: May 20, 2010

(54) OPTICAL SEMICONDUCTOR APPARATUS AND METHOD FOR PRODUCING THE SAME

(76) Inventors: Ryosuke Kondo, Tokyo (JP); Takaaki Sakai, Tokyo (JP)

Correspondence Address: CERMAK KENEALY VAIDYA & NAKAJIMA LLP, 515 EAST BRADDOCK RD SUITE B, Alexandria, VA, 22314, US

(21) Appl. No.: 12/621,035

(22) Filed: Nov. 18, 2009

(30) Foreign Application Priority Data
Nov. 18, 2008 (JP) 2008-294208

(51) Int. Cl. H01L 33/48; H01L 31/02

(52) U.S. Cl. 257/99; 438/26; 257/433; 438/64; 257/431; 257/E33.056; 257/E31.11

(57) ABSTRACT

An optical semiconductor apparatus can be configured by mounting an optical semiconductor element on a package substrate using a solder paste. The optical semiconductor apparatus can include a package substrate and a metal die pad formed on the substrate, and an optical semiconductor element bonded to the die pad with a solder material. The substrate can be made of a ceramic base material. A plurality of through holes can be formed in the substrate so that the through holes penetrate both the substrate base material and the die pad. Each of the through holes can have an inner surface where the ceramic base material is exposed. Each through hole can have an opening diameter greater than or equal to 40 μm and less than or equal to 100 μm. The plurality of through holes can be formed such that the total area of the openings of the through holes is 50% or less of the bonded area between the optical semiconductor element and the die pad including the through holes covered with the solder material. The through holes can be covered with the solder material at the upper end thereof where the optical semiconductor element and the die pad are bonded to each other.

This application claims the priority benefit under 35 U.S.C. §119 of Japanese Patent Application No. 2008-294208 filed on Nov. 18, 2008, which is hereby incorporated in its entirety by reference.

### TECHNICAL FIELD

The presently disclosed subject matter relates to an optical semiconductor apparatus and a method for producing the same.

### BACKGROUND ART

FIG. 1 is a cross-sectional view illustrating an exemplary configuration of a conventional optical semiconductor apparatus. The optical semiconductor apparatus can include: a package substrate 200 made of, for example, a resin material; conductive wirings 201 and 202 which are electrically insulated with respect to each other; an optical semiconductor element 100 disposed on the conductive wiring 201; and a transparent cover 400 provided above the optical semiconductor element 100 and configured to protect the element 100. The conductive wiring 201 can have a die pad (not shown) disposed at the end thereof, and the optical semiconductor element 100 can be electrically connected with the die pad using a bonding material 300. An electrode pad (not shown) can be provided on the upper surface of the optical semiconductor element 100, and can be electrically connected with the conductive wiring 202 through a bonding wire 203.

Recent high power optical semiconductor elements require a certain bonding material that can have a more favorable heat conductivity than a conventional silver (Ag) paste when the elements are bonded to a package substrate. Examples of such bonding materials include a gold/tin (AuSn) paste or solder, etc. For example, when an optical semiconductor element is bonded to a die pad, an AuSn paste in an appropriate amount is applied onto the die pad. Then, the optical semiconductor element is mounted on the die pad, and reflow treatment is performed to generate eutectic bonding between the optical semiconductor element and the die pad. (See, for example, Japanese Patent Application Laid-Open No. 2008-166311.)

### SUMMARY

The components contained in an exemplary AuSn paste for use as a bonding material for an optical semiconductor element are listed in Table 1, including the respective boiling points.

TABLE 1

| | | | Boiling |
|---|---|---|---|
| | Component | Content | point (° C.) |
| Powdered | Gold (Au) | 70-75% | 2700° C. |
| solder | Tin (Sn) | 17-22& | 2275° C. |
| Organic | Diethylene glycol monohexyl ether | 1-2% | 259° C. |
| solvent | C₆H₁₃(OCH₂CH₂)₂OH | | |
| | 2-Ethyl-1,3-hexane diol | <2% | 244° C. |
| | C₃H₇CH(OH)CH(C₂H₅)CH₂OH | | |
| Flux | Rosin | 3-6% | — |
| | C₁₉H₂₉COOH | | |

The AuSn paste is a bonding material paste containing a powdered solder in a ball shape, organic solvents and flux, and has a melting point of 280° C. The powdered solder includes an alloy of Au (content: 70 to 75%) and tin (content: 17 to 22%). The flux is used for removing the surface oxide film formed on the bonded surfaces, preventing the re-oxidization of solder when bonding, reducing the surface tension of molten solder, and the like. The flux is mainly composed of rosin (C₁₉H₂₉COOH, content: 3 to 6%). The organic solvent is used for dissolving the solid components and imparting an appropriate viscosity to the material. The organic solvent may contain, for example, diethylene glycol monohexyl ether (C₆H₁₃(OCH₂CH₂)₂OH, content: 1 to 2%, boiling point: 259° C.), and 2-ethyl-1,3-hexane diol (C₃H₇CH(OH)CH(C₂H₅)CH₂OH, content: 2% or less, boiling point: 244° C.).

When an optical semiconductor element is bonded to a die pad of a package substrate using an AuSn paste, the AuSn paste is applied onto the die pad. Then, the optical semiconductor element is mounted on the die pad, and the reflow treatment is performed. The die pad can have a flat surface, and accordingly, the die pad can be in close contact with the optical semiconductor element with the AuSn paste interposed therebetween. In this state, they are transferred into a reflow furnace. Here, the boiling point of the solvent contained in the AuSn paste is lower than the melting point of AuSn as shown in Table 1. In this case, if a pre-heating step is eliminated or the pre-heating is not sufficient in the reflow treatment, the solvent contained therein cannot sufficiently evaporate in advance. Namely, the environmental temperature reaches the boiling point of the solvent while the solvent is still contained in the paste. In this case, i.e., when the increasing temperature in the reflow treatment reaches the melting temperature, the solvent may abruptly boil before AuSn melts. As the optical semiconductor element and the die pad are in close contact with each other, there may be no path for discharging the gasified solvent. In this case, a so-called “chip fly” event may occur wherein the pressure of the gasified solvent blows the optical semiconductor element that is mounted on the die pad off. In order to solve or prevent this problem, pre-heating treatment can be done in a sufficient amount for the solvent to evaporate. Namely, the reflow treatment step can include a temperature profile setting for temperature control in which temperatures lower than the boiling point of the solvent being used are maintained for a predetermined time before reaching the melting temperature of AuSn, resulting in increased total time for reflow treatment.

The presently disclosed subject matter was devised in view of these and other characteristics, features, and problems, and in association with the conventional art. According to an aspect of the presently disclosed subject matter, an optical semiconductor apparatus and a method for producing the same can solve or prevent the conventional features and problems described above, including the so-called “chip fly” event in which an optical semiconductor element is blown off by the abrupt boiling of a solvent contained in a solder paste during the reflow process (by which the optical semiconductor element is mounted on a package substrate using the solder paste).

According to another aspect of the presently disclosed subject matter, an optical semiconductor apparatus can include a package substrate having a principal surface and a metal die pad formed on the principal surface, and an optical semiconductor element bonded to the die pad with a solder material interposed therebetween. In this apparatus, the package substrate can be made of a ceramic base material, and a plurality of through holes can be formed in the substrate so that they penetrate both the package substrate and the die pad. Each of the through holes can have an inner surface where the ceramic base material is exposed.

Each of the through holes can be covered with the solder material at the upper end thereof where the optical semiconductor element and the die pad are bonded to each other.

Each of the through holes can have an opening diameter greater than or equal to 40 μm and less than or equal to 100 μm. Furthermore, the plurality of through holes can be formed such that the total area of the openings of the through holes is 50% or less of the bonded area between the optical semiconductor element and the die pad including the through holes covered with the solder material.

According to still another aspect of the presently disclosed subject matter, a method for producing an optical semiconductor apparatus can include: forming a die pad made of metal on a principal surface of a package substrate made of a ceramic material; forming a plurality of through holes penetrating the die pad and the package substrate; applying a solder paste containing a powdered solder material and a solvent onto the die pad; and disposing an optical semiconductor element on the die pad with the solder paste interposed therebetween and performing reflow treatment to bond the optical semiconductor element to the die pad.

An exemplary optical semiconductor apparatus made in accordance with principles of the presently subject matter can have a plurality of through holes penetrating both the ceramic base material and the die pad constituting the substrate. These through holes can function as the discharging paths for gases generated by evaporating solvent contained in the solder paste in the reflow treatment step. Accordingly, the problems associated with chip fly due to the abrupt gas generation can be almost completely solved. This can allow for the elimination of the pre-heating treatment in the reflow treatment step, resulting in significant reduction of reflow treatment time.

### BRIEF DESCRIPTION OF DRAWINGS

These and other characteristics, features, and advantages of the presently disclosed subject matter will become clear from the following description with reference to the accompanying drawings, wherein:

FIG. 1 is a cross-sectional view illustrating the configuration of a conventional optical semiconductor apparatus;

FIG. 2 is a cross-sectional view illustrating the configuration of an optical semiconductor apparatus of one exemplary embodiment made in accordance with principles of the presently disclosed subject matter;

FIG. 3 is a top partial view showing a die pad formation area of the ceramic substrate of the exemplary embodiment of FIG. 2;

FIG. 4 is a cross-sectional view illustrating an optical semiconductor element used in the exemplary embodiment of FIG. 2;

FIG. 5 is a graph showing reflow temperature profile settings for an embodiment of an optical semiconductor apparatus of the presently disclosed subject matter (solid line) and a conventional optical semiconductor apparatus (dotted line);

FIG. 6 is a cross-sectional partial view showing a through hole formation area of the optical semiconductor apparatus of the exemplary embodiment of FIG. 2;

FIG. 7 is a cross-sectional partial view showing a through hole formation area of a comparative optical semiconductor apparatus wherein the opening diameter of the through holes are enlarged; and

FIG. 8 is a graph showing the relationship between thermal resistance and the ratio of the bonded area.

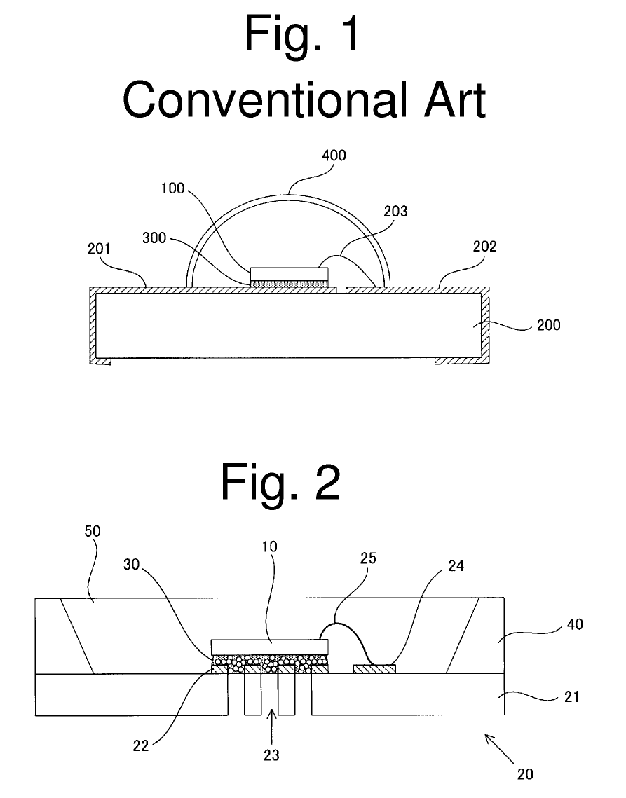

### DESCRIPTION OF EXEMPLARY EMBODIMENTS

A description will now be made below to optical semiconductor apparatuses of the presently disclosed subject matter with reference to the accompanying drawings and in accordance with exemplary embodiments. It should be noted that the same or similar components in the drawings are denoted by the same reference numerals.

FIG. 2 is a cross-sectional view illustrating the configuration of an optical semiconductor apparatus of one exemplary embodiment made in accordance with principles of the presently disclosed subject matter. FIG. 3 is a top partial view showing a die pad formation area of the ceramic substrate of the optical semiconductor apparatus.

The optical semiconductor apparatus can include: an LED chip 10 serving as an optical semiconductor element; a ceramic substrate 20 serving as a package substrate on which the LED chip 10 is mounted; a reflective member 40 disposed on the ceramic substrate 20 so as to surround the LED chip 10; and a light-transmitting resin portion 50 configured to be filled into a space surrounded by the reflective member 40 and to embed the LED chip 10 within the reflective member 40.

The ceramic substrate 20 can have a die pad 22 and a bonding pad 24 provided thereon. The LED chip 10 can be mounted on the die pad 22. A solder material can be used for bonding the LED chip 10 to the die pad 22, and can include an AuSn paste 30, for example. An electrode provided on the surface of the LED chip 10 can be connected to the bonding pad 24 on the ceramic substrate 20 using an Au wire 25. The reflective member 40 can have a circular light reflecting surface thereinside, and can be formed of alumina (Al₂O₃) or the like fine ceramics. The reflective member 40 can be bonded to the surface of the ceramic substrate 20 using, for example, a silicone resin type adhesive. The inside concave space surrounded by the reflective member 40 can be filled with, for example, a silicone resin to embed the LED chip 10. The resin is cured to form the light-transmitting resin portion 50. Accordingly, the embedded LED chip 10 and the Au wire 25 can be protected from dust, moisture, vibration, and the like. The light-transmitting resin portion 50 may contain an appropriate phosphor according to the intended or desired emission color.

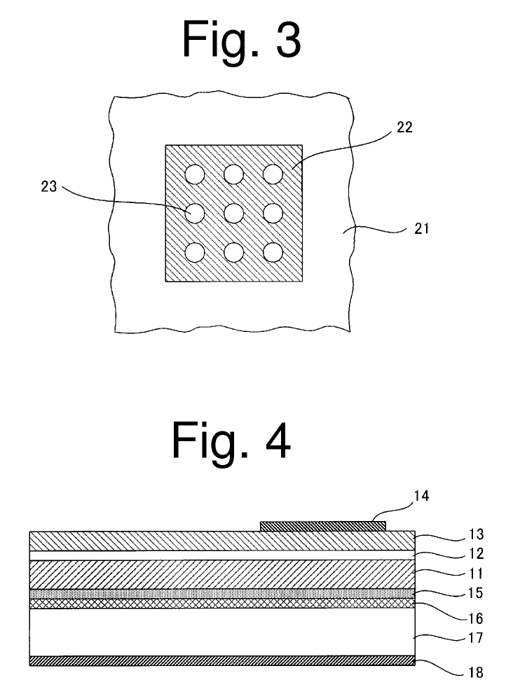

FIG. 4 is a cross-sectional view illustrating the configuration of the LED chip 10. The LED chip 10 may be an InGaN type optical semiconductor element having a laminate structure of semiconductor films of an n-GaN layer 11, a light emission layer 12, and a p-GaN layer 13, for example. A p electrode 14 formed of, for example, Ti/Al can be disposed on the top of the p-GaN layer 13. A conductive support substrate 17 made of, for example, Si can be bonded to the n-GaN layer 11 with a light reflecting film 15 and a bonding metal layer 16 interposed therebetween. An n electrode 18 formed of, for example, Ti/Al can be disposed on the surface of the conductive support substrate 17 where the LED chip 10 is to be bonded to the ceramic substrate 20. It should be noted that the LED chip 10 can have configurations other than that in which the n electrode and the p electrode are disposed on opposite surfaces. For example, the n electrode can be disposed on the same side as the p electrode (forming a flip chip type element). In this case, both of the electrodes which can be directed downward can be bonded to corresponding respective wiring patterns (die pads) on the package substrate by means of a solder material.

The base material 21 for constituting the ceramic substrate 20 can include alumina ceramics (Al₂O₃), aluminum nitride ceramics (AlN), and/or similar materials. These ceramic materials have a superior heat dissipation property to resin type base materials such as glass epoxy resin, and accordingly, can prevent the reduction in reliability and general deterioration of LED chips due to heat.

The base material 21 can include the die pad 22 on which the LED chip 10 is mounted and a bonding pad 24 to which the LED chip 10 is connected using an Au wire or the like. The die pad 22 and the bonding pad 24 can be formed by, for example, by sequentially depositing tungsten, titanium, nickel, and gold. When the LED chip 10 has a rear surface electrode like the present exemplary embodiment, the die pad 22 and the bonding pad 24 can be connected to conductive wirings (not shown) formed on the ceramic substrate so that the LED chip 10 can be supplied with power.

As shown in FIGS. 2 and 3, a plurality of through holes 23 penetrating the ceramic substrate 20 are formed in the die pad 22 formation area. Each of the through holes 23 can function as a path for discharging gasses generated by evaporating the solvent contained in the AuSn paste during the reflow treatment. Each of the through holes 23 can take a circular shape, for example, when viewed from above. Of course, the through holes 23 can be shaped differently, such as in an oval shape, square shape, rectangular shape, non-symmetrical shape, etc. The through holes 23 can also be uniformly arranged at predetermined intervals. In one mode, the opening diameter of each of the through holes 23 can be set larger than the granule diameter (approximately 16 μm to 32 μm) of the powdered solder contained in the AuSn paste in order to advantageously utilize the function of the through holes as the gas discharging paths. The upper end openings of the through holes 23 can be covered with the solder after the reflow treatment to ensure proper heat dissipation properties. In particular, the opening diameter of the through holes 23 can be formed within a range of from 40 μm to 100 μm. It should be noted that a surface treatment such as plating does not need to be applied to the inner surface of the through holes 23. Accordingly, the ceramic base material can be exposed on the inner surfaces of the through holes 23.

The ceramic substrate 20 can be prepared according to the following procedure, for example. First, a ceramic molded article is subjected to a drilling process using a drill, laser, or the like to form the plurality of through holes 23. Then, a conductive printed pattern can be formed on the area where the die pad 22 and the bonding pad 24 are to be formed. This can be done by, for example, screen printing of a conductive paste containing a high melting point metal material such as tungsten. Next, the ceramic molded article can be burned together with the high melting point metal to form a burned article. A plating film can be sequentially formed on the conductive printed pattern with the use of titanium, nickel, and gold to complete the ceramic substrate. It should be noted that the through holes 23 can be formed after the die pad 22 is printed.

Then, an AuSn paste 30, which is the solder paste, can be applied onto the die pad 22 of the ceramic substrate 20 by, for example, a dispensing method. An LED chip 10 can then be mounted on the die pad 22 on which the AuSn paste 30 has been applied. At that time, as the opening diameter of each through hole 23 is larger than the granule diameter of the powdered solder contained in the AuSn paste, the excess AuSn paste 30 can enter the inside of the through holes 23 by the pressure present during the mounting operation. This can prevent the solder from climbing the side surfaces of the LED chip 10 even when the amount of the AuSn paste 30 that is applied is too much. Accordingly, it is easy to control the applied amount of the AuSn paste 30 and control the pressure by the mounter. In general, the larger the amount of the solder paste that is applied, the lower the void ratio (the ratio of the void area in the solder with respect to the bonded area) is. In the optical semiconductor apparatus of the present exemplary embodiment, as the climbing up of the solder is prevented, the applied amount of the AuSn paste 30 can be increased relatively, thereby reducing the void ratio. This can provide a favorable heat dissipation property.

The ceramic substrate 20 on which the LED chip 10 has been mounted can be transferred into a reflow furnace. Heating treatment in the reflow furnace can melt the AuSn paste 30. Then, the LED chip 10 can be bonded onto the die pad 22 by cooling. During the reflow treatment, the solvent contained in the AuSn paste 30 can evaporate, and the gases that are generated can be discharged to the outside via the through holes 23. At that time, the opening diameter of each of the through holes 23 is larger than the particle diameter of the powdered solder, and accordingly, the upper ends of the through holes 23 are prevented from being clogged with the solder particles and can properly function as gas discharging paths.

As described above, even when gases derived from the solvent contained in the AuSn paste are generated, the problems associated with chip fly can be almost completely solved because the through holes 23 can each function as gas discharging paths. This can eliminate the need for a pre-heating treatment in the reflow treatment step, which has previously been provided to prevent the chip fly problems, thus resulting in a possible significant reduction of reflow treatment time when compared with conventional reflow treatment time.

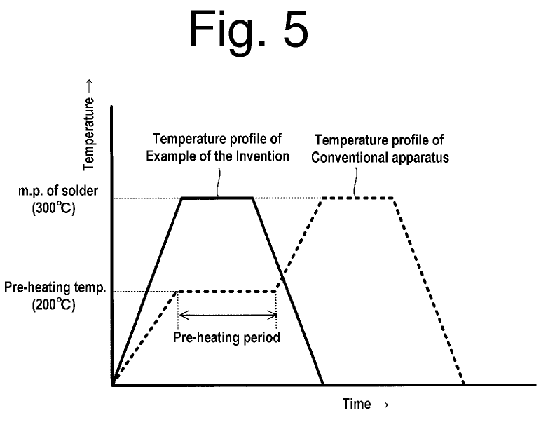

FIG. 5 is a graph showing the reflow temperature profile settings for an embodiment of an optical semiconductor apparatus of the presently disclosed subject matter (solid line) and a conventional optical semiconductor apparatus (dotted line).

In the conventional optical semiconductor apparatus process where no through holes are provided in the die pad and the substrate, the production method includes a pre-heating treatment including holding the apparatus at a predetermined temperature lower than the boiling point of the solvent (for example, approximately 200° C.) for a preset period of time before the temperature reaches the melting temperature of the AuSn paste (approximately, for example, 300° C.) in order to avoid the chip fly phenomenon. The solvent contained in the AuSn paste can evaporate during this pre-heating treatment before the AuSn melts, and can be discharged outside. After the pre-heating treatment is completed, the temperature is increased to the melting temperature of the AuSn and maintained for a preset period of time. Then, the system is cooled to complete the solder bonding.

On the other hand, the exemplary optical semiconductor apparatus 1 is provided with a plurality of through holes 23 in the die pad 22 and the substrate 20. The through holes 23 each can function as gas discharging paths. Accordingly, the method for producing the optical semiconductor apparatus 1 does not require the pre-heating treatment for gasifying the solvent. In other words, the temperature profile can be set such that the temperature rising rate (gradient) can be increased (can be steeper) at an early stage of the reflow treatment to rapidly reach the melting temperature of the AuSn (for example, 3 to 40° C./sec). The temperature of the solvent reaches its boiling point during this temperature rising period, but chip fly does not occur because the gasified solvent can be discharged outside via the through holes. Then, the system is maintained at the melting temperature of the AuSn paste for 5 to 30 seconds, for example, and then cooling can complete the solder bonding.

As discussed above, since the optical semiconductor apparatus 1 can be configured as described above, the pre-heating treatment can be eliminated in the reflow treatment step, resulting in significant reduction of reflow treatment time. This can improve the productivity of optical semiconductor apparatus manufacture. The conventional stepped heating treatment including the pre-heating treatment is not required, and accordingly, the strict temperature profile control is not required. Thus, the process does not require a formal reflow furnace for temperature control, but can use a simple hot plate for performing the reflow process. Because the optical semiconductor apparatus of the present exemplary embodiment uses a ceramic substrate 20 having a high heat conductivity, the reflow period can be reduced as compared with the case of a resin-based substrate.

Incidentally, when the solder is kept at high temperature for a longer period of time in the reflow treatment step, moisture vapor may be generated due to the oxidative reaction of the solder, and can remain inside the solder. The generated moisture vapor may be a cause for void generation in the solder. In the optical semiconductor apparatus 1 of the present exemplary embodiment, a ceramic substrate 20 having a high heat conductivity is used, therefore the temperature gradient of the solder bonding portion of the process can also be steep. This temperature control can melt the solder prior to any significant oxidation reaction. Furthermore, as the generated moisture vapor can also be discharged outside via the through holes 23, the generation of a void in the solder can be effectively prevented.

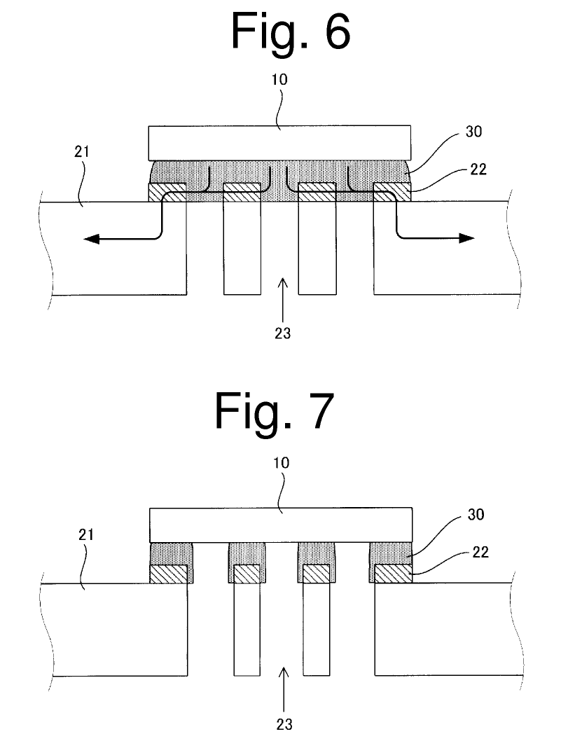

FIG. 6 is a cross-sectional partial view showing the through hole formation area of the optical semiconductor apparatus 1 after the reflow treatment. As described above, the ceramic base material 21 is exposed on the inner surfaces of the through holes 23. The surface energy of ceramics is smaller than that of metal, and accordingly, the solder wettability to the ceramics is remarkably low. Accordingly, even when the molten AuSn paste 30 enters the through holes 23 during the mounting operation of the LED chip 10, the solder can be spread over the die pad 22 in the reflow treatment step because of the solder wettability to the metal die pad. This can prevent the AuSn solder from adhering to the inner surfaces of the through holes 23. In other words, this can prevent the AuSn solder from running out via the through holes 23. If the solder runs out, the amount of solder at the bonding interface between the LED chip 10 and the die pad 22 is decreased, and the heat dissipating property of the optical semiconductor apparatus may deteriorate.

Since the ceramic base material 21 can be exposed on the inner surfaces of the through holes 23, deterioration of the heat dissipation property can also be prevented.

Although the opening diameter of each through hole 23 can be 100 μm or less, the AuSn paste 30 can be prevented from running off from the through holes 23 as described above. Accordingly, the upper ends of the through holes 23 can be covered with the AuSn solder. Namely, at the upper ends of the through holes 23, the adjacent solder portions can be joined to form a bridge thereover. This means that there can be no area where the solder cannot be applied corresponding to the areas where the through holes 23 are formed (the not-applied area would also serve as a void in the solder). Accordingly, in the optical semiconductor apparatus of the present exemplary embodiment, the heat generated by the LED chip 10 can be dissipated, even at the through holes formation areas, through the heat dissipation paths, as shown in FIG. 6 by arrows, to the ceramic substrate 20.

By adjusting the opening diameter of each through hole 23 to be 100 μm or less, the generation of voids in the solder at the through hole formation areas can be prevented, thereby minimizing adverse effects on the heat dissipation property.

FIG. 7 is a cross-sectional view partially showing the through hole formation area of a comparative optical semiconductor apparatus wherein the opening diameter of the through holes are enlarged to be equal to or greater than 100 μm. In this case, due to the large opening diameter, it is difficult to form bridges across the upper ends of the through holes 23. This can form voids in the solder corresponding to the through hole 23 formation areas (spaces in the solder paste 30 in FIG. 7). Accordingly, the heat dissipation paths as those shown in FIG. 6 of the presently disclosed subject matter cannot be ensured, and the heat dissipation property may deteriorate.

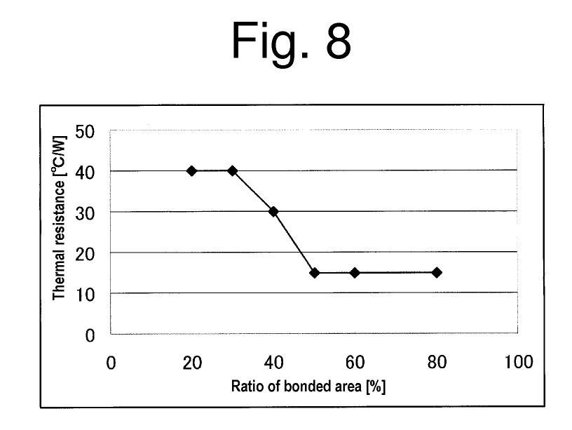

FIG. 8 is a graph showing the relationship between the thermal resistance and the ratio of the bonded area for various samples using several ceramic substrates without through holes. The ratio of the bonded area is the ratio of the area of the solder bonded portion to the area of the bottom of the optical semiconductor element. In these samples, the die pad area can be equal to the bottom area of the optical semiconductor element. As the voids in the solder are generated, the ratio of the bonded area lowers.

As shown in the graph of FIG. 8, when the ratio of the bonded area becomes 50% or lower, in particular, the thermal resistance remarkably increases. As a result, the heat dissipation property deteriorates.

Accordingly, the relationship between the total opening area of all through holes and the area of the bonded portions between the die pad and the optical semiconductor element via the solder paste (including the through hole formation portions, hereinafter referred to as “bonded area”) should be controlled. In the presently disclosed subject matter, the opening area of all through holes may be 50% or less of the bonded area. In other words, the opening area of all through holes can be set to be 50% or less of the smaller one of the die pad area (corresponding to the contour area including the through hole formation area) and the bottom of the optical semiconductor element which defines the bonded area.

In the above exemplary embodiment, the LED chip can have a pair of electrodes one on the top surface and the other on the rear or bottom surface, and can be supplied with power through the die pad and the bonding pad. However, the presently disclosed subject matter is not limited to this particular mode. The LED chip can be an LED chip having a pair of electrodes on the same side. In this case, the LED chip can be supplied with power through a plurality of bonding pads and conductive wires without a die pad intervening.

As described above, the optical semiconductor apparatus made in accordance with the principles of the presently subject matter can have a plurality of through holes in the die pad on the ceramic substrate so that the holes penetrate both the ceramic base material and the die pad. These through holes can function as discharging paths for gases generated by evaporating the solvent that is contained in the solder paste in the reflow treatment step. Accordingly, the problems associated with chip fly due to the abrupt gas generation can be almost completely solved or prevented. This can eliminate the need for a pre-heating treatment in the reflow treatment step, resulting in significant reduction of reflow treatment time. As each through hole can have an opening diameter equal to or greater than 40 μm and 100 μm or less, the through holes can effectively function as the gas discharging paths. Furthermore, in this opening diameter range, the solder bonded area can be ensured even at the through hole formation areas, thereby minimizing the adverse effect to the heat dissipation property. Furthermore, the plurality of through holes can be formed such that the total area of the openings of the through holes is 50% or less of the bonded area between the optical semiconductor element and the die pad including the through holes covered with the solder material, thereby almost eliminating the adverse effect with respect to the heat dissipation property.

It will be apparent to those skilled in the art that various modifications and variations can be made in the presently disclosed subject matter without departing from the spirit or scope of the presently disclosed subject matter. Thus, it is intended that the presently disclosed subject matter cover the modifications and variations of the presently disclosed subject matter provided they come within the scope of the appended claims and their equivalents. All related art references described above are hereby incorporated in their entirety by reference.

What is claimed is:

1. An optical semiconductor apparatus comprising:
a package substrate having a principal surface and a metal die pad formed on the principal surface, the package substrate being made of a ceramic base material, wherein a plurality of through holes are formed in the substrate so that the through holes penetrate both the base material and the die pad, each of the through holes having an inner surface in which the ceramic base material is exposed; and
an optical semiconductor element bonded to the die pad with a solder material interposed between the optical semiconductor element and the die pad.

2. The optical semiconductor apparatus according to claim 1, wherein each of the through holes is covered with the solder material at an upper end of each of the through holes where the optical semiconductor element and the die pad are bonded to each other.

3. The optical semiconductor apparatus according to claim 1, wherein each of the through holes has an opening area with a diameter greater than or equal to 40 μm and less than or equal to 100 μm, and
the plurality of through holes are formed such that a total area of the opening areas of the through holes is 50% or less of a bonded area between the optical semiconductor element and the die pad, the bonded area including a total area of the opening areas of the through holes covered with the solder material.

4. The optical semiconductor apparatus according to claim 2, wherein each of the through holes has an opening area with a diameter greater than or equal to 40 μm and less than or equal to 100 μm, and
the plurality of through holes are formed such that a total area of the opening areas of the through holes is 50% or less of a bonded area between the optical semiconductor element and the die pad, the bonded area including a total area of the opening areas of the through holes covered with the solder material.

5. A method for producing an optical semiconductor apparatus comprising:
forming a die pad made of metal on a principal surface of a package substrate made of a ceramic material;
forming a plurality of through holes penetrating the die pad and the package substrate;
applying a solder paste containing a solder material and a solvent onto the die pad; and
disposing an optical semiconductor element on the die pad with the solder paste interposed between the optical semiconductor element and the die pad, and performing reflow treatment to bond the optical semiconductor element to the die pad.

6. The method for producing an optical semiconductor apparatus according to claim 5, wherein applying a solder paste includes covering each of the through holes with the solder material at an upper end of each of the through holes where the optical semiconductor element and the die pad are bonded to each other.

7. The method for producing an optical semiconductor apparatus according to claim 5, wherein each of the through holes has an opening area with a diameter greater than or equal to 40 μm and less than or equal to 100 μm, and
the plurality of through holes are formed such that a total area of the opening areas of the through holes is 50% or less of a bonded area between the optical semiconductor element and the die pad, the bonded area including a total area of the opening areas of the through holes covered with the solder material.

8. The method for producing an optical semiconductor apparatus according to claim 6, wherein each of the through holes has an opening area with a diameter greater than or equal to 40 μm and less than or equal to 100 μm, and
the plurality of through holes are formed such that a total area of the opening areas of the through holes is 50% or less of a bonded area between the optical semiconductor element and the die pad, the bonded area including a total area of the opening areas of the through holes covered with the solder material.

9. The method for producing an optical semiconductor apparatus according to claim 5, wherein the solder material is a powdered solder material.

10. The method for producing an optical semiconductor apparatus according to claim 5, further comprising:
heating the package substrate, die pad, and solder material until the solvent boils from the solder material and escapes via the through holes in the package substrate.

11. The optical semiconductor apparatus according to claim 1, wherein each of the through holes has a longitudinal central axis that intersects the optical semiconductor element.

12. The optical semiconductor apparatus according to claim 1, wherein each of the through holes has a longitudinal central axis, a first end of each of the through holes is plugged by the solder material while a second opposite end of each of the through holes is exposed to atmosphere.

13. The optical semiconductor apparatus according to claim 1, wherein the solder material extends as a single continuous layer across all of the through holes and across the die pad.

14. The optical semiconductor apparatus according to claim 1, wherein the solder material includes a powdered solder and a solvent.

15. The optical semiconductor apparatus according to claim 1, wherein the optical semiconductor element includes at least one of a light emitting device and a light receiving device.

16. An optical semiconductor apparatus comprising:
a substrate having a top surface;
a die pad located adjacent the top surface of the substrate; and
an optical semiconductor element bonded to the die pad with a solder material interposed between the optical semiconductor element and the die pad, wherein
the substrate includes a plurality of through holes, at least a portion of the through holes being located under the optical semiconductor element such that a longitudinal central axis of each of the portion of through holes intersects the optical semiconductor element, and each of the portion of through holes has a first end plugged by the solder material and a second opposite end exposed to atmosphere such that any gases emitted from the solder material during manufacture of the optical semiconductor apparatus can escape via the portion of through holes.

17. The optical semiconductor apparatus according to claim 16, wherein each of the through holes has an opening area greater than or equal to 1256 μm² and less than or equal to 7854 μm², and
the plurality of through holes are formed such that a total area of the opening areas of the through holes is 50% or less of a bonded area between the optical semiconductor element and the die pad, the bonded area including a total area of the opening areas of the through holes.

18. The optical semiconductor apparatus according to claim 16, wherein the solder material extends as a single continuous layer across all of the portion of through holes and across the die pad.

19. The optical semiconductor apparatus according to claim 16, wherein the solder material includes a powdered solder and a solvent.

20. The optical semiconductor apparatus according to claim 16, wherein the die pad includes a metal material, and the substrate includes a ceramic material.
